(19) United States
(12) Patent Application Publication
(10) Pub. No.: US 2009/0128043 A1
(43) Pub. Date: May 21, 2009

(54) LIGHT SENSING APPARATUS AND DISPLAY DEVICE THEREOF

(75) Inventors: Wen-Chun Wang, Taichung City (TW); Chun-Chin Chang, Taichung County (TW); Ching-Fu Hsu, Taichung County (TW); Hsi-Rong Han, Taichung County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: WINTEK CORPORATION, Taichung (TW)

(21) Appl. No.: 12/275,442

(22) Filed: Nov. 21, 2008

(30) Foreign Application Priority Data
Nov. 21, 2007 (TW) 96144166

(51) Int. Cl. H05B 37/02; H01L 31/0232

(52) U.S. Cl. 315/158; 257/431

(57) ABSTRACT

A light sensing apparatus and a display device thereof are provided. The light sensing apparatus comprises a filtering device and a light sensing device. The filtering device filters off a part of the ambient light and outputs the other part of the ambient light. The light sensing device outputs a sensing signal according to the other part of the ambient light.

This application claims the benefit of Taiwan application Serial No. 96144166, filed Nov. 21, 2007, the subject matter of which is incorporated herein by reference.

### BACKGROUND OF THE INVENTION

1. Field of the Invention

The invention relates in general to a light sensing apparatus and a display device thereof and more particularly to a light sensing apparatus with light sensing function and a display device thereof.

2. Description of the Related Art

Along with the maturity of the technology of display device, more and more electronic devices further incorporate the display device with operating functions. For example, the user can view an image or a text message from the display device of mobile phone or personal digital assistant; meanwhile, the user can operate the electronic device via the messages displayed on the display device.

However, the brightness of the display device is provided by a backlight, and the longer the backlight is turned on, the more power will be consumed. Furthermore, the brightness of the ambient light directly affects user's visual comfort. Therefore, how to adjust the brightness of the backlight according to the ambient brightness has become an imminent issue to be resolved.

### SUMMARY OF THE INVENTION

The invention is related to a light sensing apparatus and a display device thereof. When equipped with the light sensing apparatus, the display device is capable of adjusting the brightness of the backlight source according to the ambient brightness.

According to a first aspect of the present invention, a light sensing apparatus is provided. The light sensing apparatus comprises a filtering device and a light sensing device. The filtering device filters off a part of the ambient light and allows the other part of ambient light for transmission. The light sensing device outputs a sensing signal according to the other part of the ambient light.

According to a second aspect of the present invention, a display device is provided. The display device comprises a display panel, a backlight source, a backlight control circuit and a backlight driving circuit. The display panel has a display region and a peripheral region, wherein a light sensing apparatus is disposed in the peripheral region. The light sensing apparatus comprises a filtering device and a light sensing device. The filtering device filters off a part of the ambient light, such as shorter wavelength portion, and outputs the other part of the ambient light such as longer wavelength portion. The light sensing device outputs a sensing signal according to the other part of the ambient light that emitted on the light sensing device.

Besides, the backlight control circuit comprises an amplification unit, an analog/digital converter and a micro-processor. On the part of the backlight control circuit, the amplification unit outputs an analog signal according to a sensing signal and a reference signal. After the analog/digital converter converts the analog signal into a digital signal, the micro-processor performs operation on the digital signal and outputs a backlight control signal.

The backlight driving circuit outputs a backlight driving signal to the backlight source according to the backlight control signal of the backlight control circuit, so that the brightness of the backlight source is adjusted according to the ambient brightness.

The invention will become apparent from the following detailed description of the preferred but non-limiting embodiments. The following description is made with reference to the accompanying drawings.

### BRIEF DESCRIPTION OF THE DRAWINGS

FIG. 1 is a schematic illustration showing a display device according to a preferred embodiment of the invention;

FIG. 2 is a schematic illustration showing a backlight control circuit;

FIG. 3 is a circuit diagram of an amplification unit;

FIG. 4 is a schematic illustration showing a light sensing apparatus;

FIG. 5 shows a partial cross-sectional diagram of the display panel 11;

FIG. 6 shows a circuit diagram of a light sensing device;

FIG. 7 shows another circuit diagram of the light sensing device;

FIG. 8 shows another circuit diagram of the light sensing device;

FIG. 9 shows another circuit diagram of the light sensing device;

FIG. 10 shows another circuit diagram of the light sensing device;

FIG. 11 shows a structural diagram of a light sensing apparatus according to the first embodiment of the invention;

FIG. 12 shows a structural diagram of the filter layer 432 with an opening;

FIG. 13 shows a structural diagram of a light sensing apparatus according to the second embodiment of the invention;

FIG. 14 shows a detailed illustration of the filter layer 434;

FIG. 15 shows another detailed illustration of the filter layer 434; and

FIG. 16 shows a structural diagram of a light sensing apparatus according to the third embodiment of the invention.

### DETAILED DESCRIPTION OF THE INVENTION

Display Device:

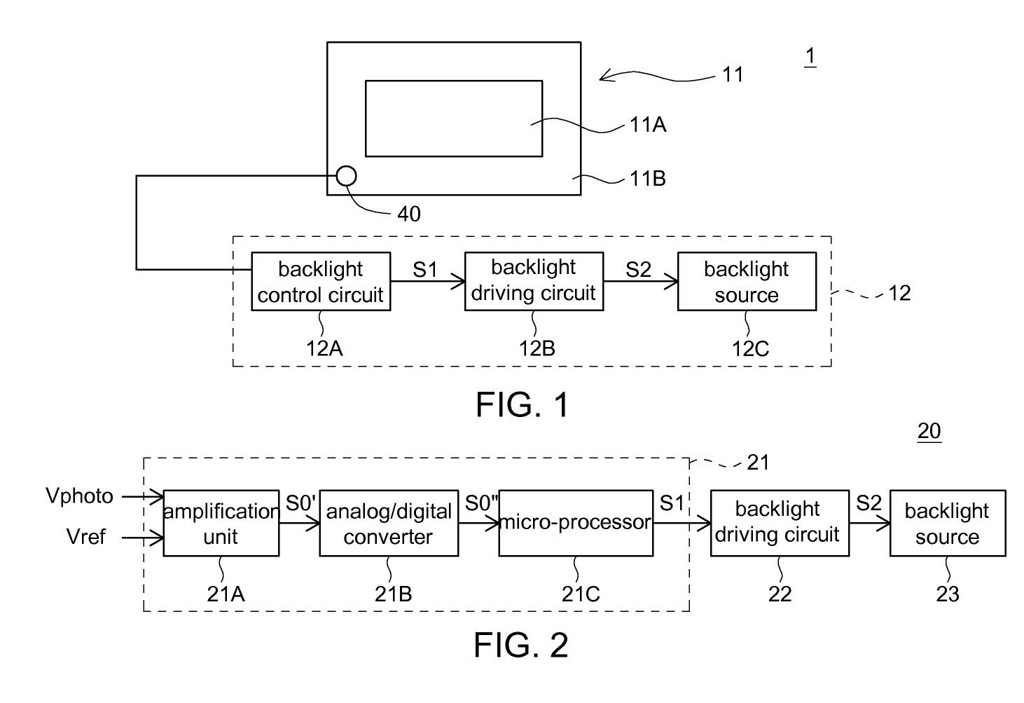

Referring to FIG. 1, a schematic illustration of a display device according to an embodiment of the invention is shown. The display device is used in an electronic device such as a mobile phone, a notebook, a monitor, or a personal digital assistant. The display device 1 comprises a display panel 11 and a backlight system 12, wherein the display panel 11 is made from amorphous silicon, single-crystal silicon, micro-crystal, or poly-crystal silicon. The backlight system 12 automatically adjusts the intensity of the backlight outputted to the display panel 11 according to the intensity of ambient brightness.

Furthermore, the display panel 11 comprises a display region 11A (also called active region) and a peripheral region 11B (also called non-display region), wherein the peripheral region 11B is formed in the peripheral of the display region 11A. The display region 11A has a pixel array for generating an image frame according to the inputted image signal. The peripheral region 11B comprises at least one light sensing apparatus 40 for correspondingly outputting a sensing signal Vₚₕₒₜₒ to the backlight system 12 according to the intensity of the ambient brightness. The light sensing apparatus 40 and the pixels of the display region 11A (including color filter and active element) are simultaneously-fabricated in the same manufacturing processes.

The backlight system 12 further comprises a backlight control circuit 12A, a backlight driving circuit 12B and a backlight source 12C. The backlight control circuit 12A is for receiving and processing the sensing signal Vₚₕₒₜₒ and then outputting a backlight control signal S1. The backlight driving circuit 12B, according to the backlight control signal S1, outputs a backlight driving signal S2 to the backlight source 12C to adjust the intensity of the light outputted from the backlight source 12C.

As the intensity of the backlight outputted to the display panel 11 by the backlight system 12 is dynamically adjusted according to the change of the ambient brightness, the display device 1 at least has the following advantages of:
1. Increasing the additional value of the electronic device equipped with a display device 1;
2. Saving power consumption;
3. Increasing user's visual comfort;
4. Simplifying manufacturing processes and reducing manufacturing costs as the light sensing apparatus 40 and the pixels of the display region 11A are synchronically formed;
5. Efficiently utilizing the area of the peripheral region 11B rather than occupying the display region 11A as the light sensing apparatus 40 is disposed in the peripheral region 11B.
6. Providing excellent light sensing ability by adjusting the number of the light sensing apparatus 40.

Backlight Control Circuit:

Referring to FIG. 2, a schematic illustration of a backlight control circuit is shown. The backlight control circuit 21 is an example of backlight control circuit 12A shown in the FIG. 1. The backlight control circuit 21 comprises an amplification unit 21A, an analog/digital converter 21B and a micro-processor 21C. The amplification unit 21A outputs an analog signal S0′ according to a sensing signal Vₚₕₒₜₒ and a reference signal V_{ref}. The analog/digital converter 21B converts the analog signal S0′ into a digital signal S0″. The micro-processor 21C performs operation on the digital signal S0″ and then outputs a backlight control signal S1. The backlight driving circuit 22, according to the backlight control signal S1, outputs a backlight driving signal S2 to the backlight source 23 to adjust the intensity of the light.

Amplification Unit:

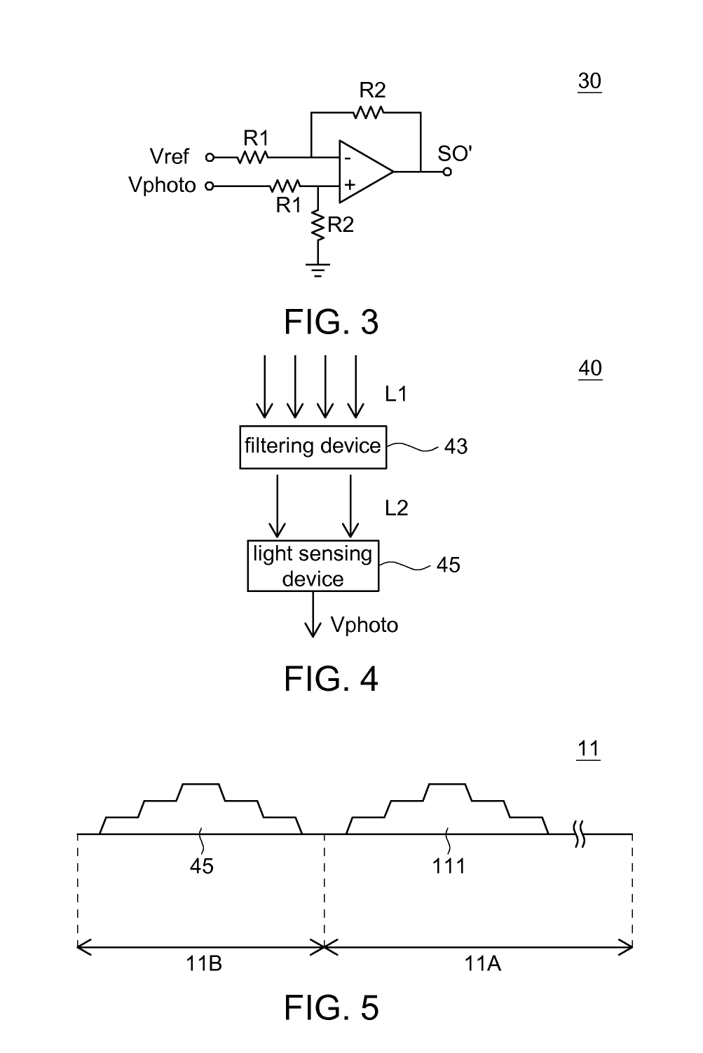

Referring to FIG. 3, a circuit diagram of an amplification unit is shown. FIG. 2 shows an amplification unit 21A such as a differential amplifier 30, and the voltage of the analog signal S0′ is equal to (R2/R1)×(V_{ref}−Vₚₕₒₜₒ). The amplification ratio of the differential amplifier changes along with the ratio of the resistors R2 and R1. By selecting appropriate resistors R2 and R1, the voltage of the analog signal S0′ within a particular range is produced. However, the amplification unit of the invention is not limited to the differential amplifier of the present embodiment, and the differential amplifier used in the invention can be replaced by any amplification elements having the same functions.

Light Sensing Apparatus:

Referring to both FIG. 4 and FIG. 5. FIG. 4 shows a schematic illustration of a light sensing apparatus. FIG. 5 shows a partial cross-sectional diagram of the display panel 11. The light sensing apparatus 40 comprises a filtering device 43 and a light sensing device 45. The light sensing device 45 is a TFT with particular aspect ratio for forming a light sensing transistor. Besides, the light sensing device 45 can become a light sensing diode by appropriate connection of the terminal of the light sensing device 45. As the light sensing device 45 and the TFT 111 of the pixels in the display region 11A are simultaneously-fabricated, the display panel 11 provides excellent light sensing ability without any additional light sensing elements. Thus, not only the manufacturing process is simplified but also the manufacturing cost is reduced. Further, the size of light sensing device 45 may be larger than the TFT 111 of the pixels in the display region 11A for achieving better performance.

Moreover, in order to let the material of TFT avoid the Staebler-Wronski effect which decreases photoelectrical efficiency and shortens lifespan after exposed to a strong light, the part of the ambient light L1 is filtered by the filtering device 43 first and then the other part of the ambient light L2 is outputted to the light sensing device 45. The light sensing device 45 outputs a sensing signal Vₚₕₒₜₒ according to the residual part of the ambient light L2.

The ambient light is filtered by the filtering device 43 before entering into the light sensing device 45. It can not only effectively preventing the light sensing device 45 from aging but also increasing the lifespan of the light sensing apparatus 40. In other words, the filtering device 43 may filter out a part of light which consists of at least one kind of undesireable wavelength such as ultraviolet or blue light to retard the aging speed of the light sensing device 45.

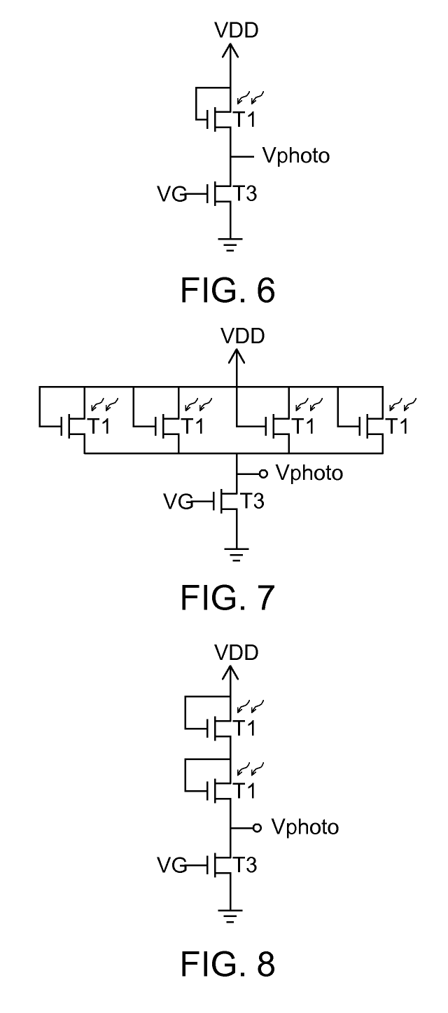

Referring to FIG. 6, a circuit diagram of a light sensing device is shown. The light sensing device 45 such as a light sensing transistor T1 is serially connected to the transistor T3. The control terminal of the light sensing transistor T1 is electrically connected to the first end of the light sensing transistor T1 to form a light sensing diode. The first end of the light sensing transistor T1 receives a reference voltage VDD, and the second end of the light sensing transistor T1 is coupled to the first end of the transistor T3. The gate of the transistor T3 receives a gate voltage VG, and the second end of the transistor T3 is grounded.

When the light sensing transistor T1 receives the ambient light, the equivalent resistance of the transistor T1 changes along with the intensity of the light and then the voltage of the sensing signal Vₚₕₒₜₒ would be changed.

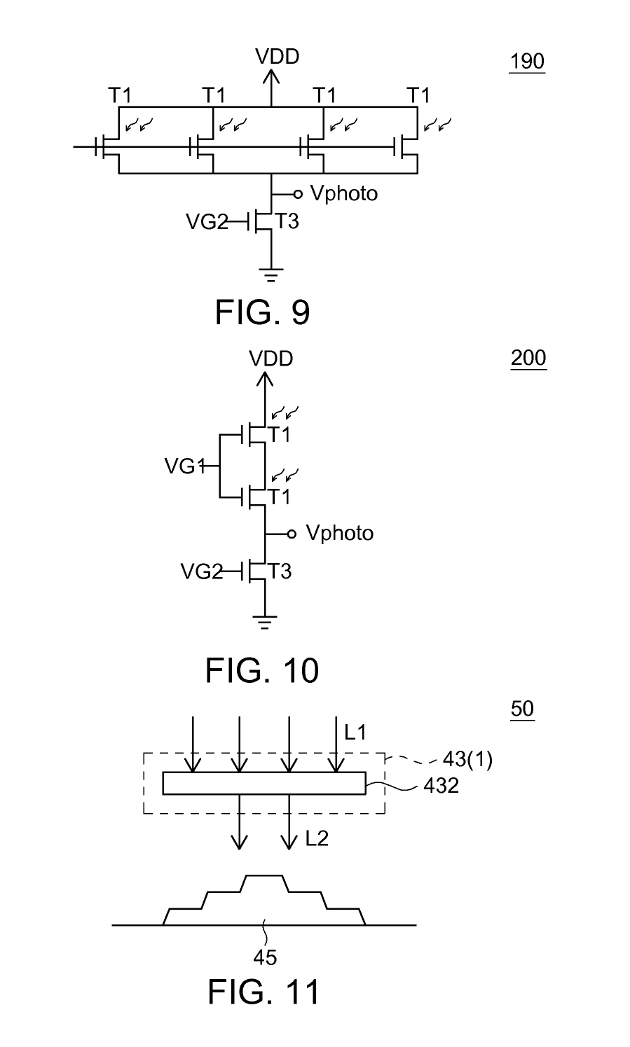

Referring to FIG. 7 to FIG. 10, the other circuit diagrams of the light sensing device are shown. The light sensing diodes which are formed form light sensing transistors Ti are connected in parallel (as indicated in FIG. 7) or in serial (as indicated in FIG. 8) so that the light sensing device output a sensing signal Vₚₕₒₜₒ. Besides, the light sensing transistors T1 are connected in parallel (as indicated in FIG. 9) or in serial (as indicated in FIG. 10) so that the light sensing device output a sensing signal Vₚₕₒₜₒ.

The light sensing apparatus 40 is exemplified in a first embodiment to a third embodiment hereinafter. However, the invention is not limited thereto, and anyone who is skilled in the technologies of the invention will understand that any modifications and similar arrangements and procedures according to the spirit of the invention are within the scope of protection of the invention.

### First Embodiment

Referring to FIG. 11, a structural diagram of a light sensing apparatus according to a first embodiment of the invention is shown. The light sensing apparatus 40 is exemplified by a light sensing apparatus 50, and the filtering device 43 is is exemplified by a filtering device 43(1). The filtering device 43(1) comprises a filter layer 432 that is over the light sensing device 45. The filter layer 432 is a polarizer, a black matrix (BM), or a combination of the polarizer and the BM.

If the filter layer 432 is a BM, the filter layer 432 has a predetermined thickness allowing the light L1 of the ambient light to leak a suitable intensity of the light L2 irradiated onto the light sensing device 45. In other words, the thickness of BM is designed to allow some part of ambient light for passing through and the light sensing device 45 can function well as long as it receives adequate energy of ambient light. The predetermined thickness of the filter layer 432 is preferably smaller than the thickness of the BM disposed on the display region. For example, if the filter layer 432 is a BM, the predetermined thickness ranges from 0.01 μm to 1 μm (inclusive of 0.01 μm and 1 μm).

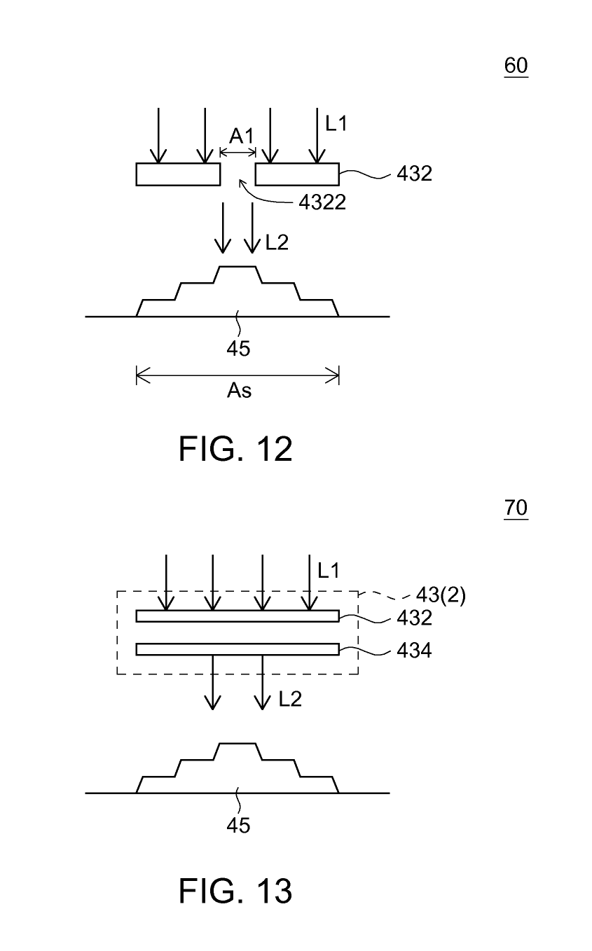

Referring to FIG. 12, a structural diagram of the filter layer 432 with an opening is shown. The light sensing apparatus 40 of FIG. 4 is the light sensing apparatus 60 of FIG. 12 for example. Besides, an opening 4322 with predetermined opening area A1 can be disposed above the filter layer 432. The size of the predetermined opening area A1 just allows the ambient light to leak suitable intensity of light L2 irradiated onto the light sensing device 45 via the filter layer 432. For example, if the filter layer 432 is a BM, the predetermined opening area A1 is 10% to 90% (inclusive of 10% and 90%) of the light sensing device 45.

### Second Embodiment

Referring to FIG. 13, a structural diagram of a light sensing apparatus according to a second embodiment of the invention is shown. The light sensing apparatus 40 of FIG. 4 is exemplified by a light sensing apparatus 70 of FIG. 13. The filtering device 43(2) comprises a filter layer 432 along with a filter layer 434, wherein the filter layer 432 can be a BM and the filter layer 434 is disposed between the filter layer 432 and the light sensing device 45. The filter layer 434 can be formed by one layer of color filter or by multiple layers of color filters.

In the same manufacturing process, the filter layer 434 of the filtering device 43(2) shown in FIG. 4 and the color filter disposed on the display region 11A shown in FIG. 1 are fabricated simultaneously. As a result, the manufacturing process is simplified and the cost is reduced to form a improved light sensing apparatus 40.

According to an alternative embodiment, the filter layer 432 is omitted and only the filter layer 434 is used as a filtering device 43(2). And other elements or operations similar to the above embodiments are not repeated.

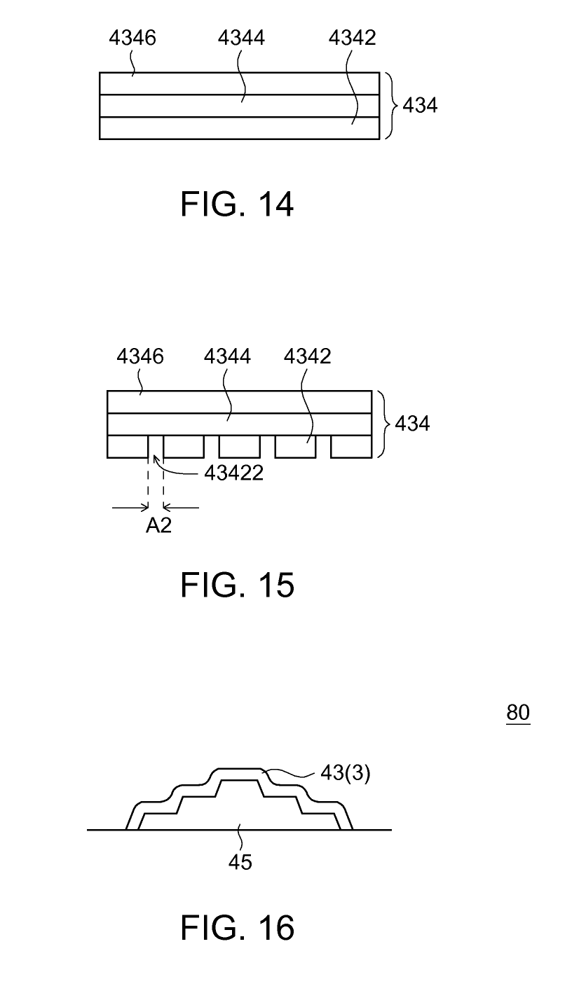

Referring to FIG. 14, a detailed illustration of the filter layer 434 is shown. The filter layer 434 comprises a first color filter layer 4342, a second color filter layer 4344 and a third color filter layer 4346, wherein the first color, the second color and the third color are red, green and blue respectively. The thickness of the first color filter layer 4342, and the second color filter layer 4344 and the third color filter layer 4346 respectively ranges from 0.3 μm to 3 μm (inclusive of 0.3 μm and 3 μm).

The filter layer 434 is not limited using three different color filter layers, and can be formed using two different color filter layers or even one single color filter layer alone. For example, two layers, a red filter layer and a green filter layer, might be enough to produce satisfactory effect because such two-layer filter 434 filters off the blue light, the shorter wavelength of the ambient light, not only alleviating the aging of the light sensing device 45 caused by the ambient light but also prolonging the lifespan of the light sensing device 45.

Referring to FIG. 15, another detailed illustration of the filter layer 434 is shown. Besides, the first color filter film 4342 can have at least an opening 43422 with predetermined opening area A2. The size of the predetermined opening area A2 just allows the ambient light to leak suitable intensity of the light L2 via the filter layers 432 and 434. The predetermined opening area A2 is 10% to 100% (inclusive of 10% and 100%) of the area of the light sensing device 45.

### Third Embodiment

Referring to FIG. 16, a structural diagram of a light sensing apparatus according to a third embodiment of the invention is shown. The light sensing apparatus 40 of FIG. 4 is exemplified a light sensing apparatus 80 of FIG. 16. The third embodiment differs with the first embodiment in that the filtering device 43(2) is differs with a filtering device 43(3), which covers the light sensing device 45. The filtering device 43(3) covers the light sensing device 45 and includes metallic material, organic material or inorganic material. For instance, the material may be aluminum, silicon nitride, molybdenum, ink or the combination of above-mentioned materials . . . etc.

If the filtering device 43(3) is made from aluminum, the thickness of the filtering device 43(3) ranges from 10 Å to 500 Å (inclusive of 10 Å and 500 Å) for example. Furthermore, if the filtering device 43(3) is made from silicon nitride, the thickness of the filtering device 43(3) ranges from 1 μm to 5 μm (inclusive of 1 μm and 5 μm). Besides, if the filtering device 43(3) is made from molybdenum, the thickness of the filtering device 43(3) ranges from 10 Å to 500 Å (inclusive of 10 Å and 500 Å). Moreover, if the filtering device 43(3) is made from ink, the thickness of the filtering device 43(3) ranges from 0.1 μm to 5 μm (inclusive of 0.1 μm and 5 μm).

According to the above disclosure, the light sensing apparatus of the invention effectively senses the brightness of the ambient light and dynamically adjusts the brightness of the backlight source according to the ambient brightness, hence largely reducing unnecessary power waste. Besides, the light sensing apparatus and the display device disclosed in the above embodiments of the invention filters off part of the ambient light by a filtering device, not only alleviating the aging of the sensing elements caused by the Staebler-Wronski effect but also prolonging lifespan and reliability of the light sensing device. On the other hand, as the light sensing apparatus of the invention can be formed in the display device in an ordinary manufacturing process, the manufacturing cost is further reduced.

While the invention has been described by way of several embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light sensing apparatus disposed on a non-display region of a display panel, wherein the light sensing apparatus comprises:
a filtering device for filtering a part of the ambient light and outputting the other part of the ambient light; and
a light sensing device oppositely disposed on one side of the filtering device for outputting a sensing signal according to the other part of the ambient light.

2. The light sensing apparatus according to claim 1, wherein the filtering device comprises:
a first filter layer having a predetermined thickness allowing the filtering device to output the other part of the ambient light to the light sensing device.

3. The light sensing apparatus according to claim 2, wherein the first filter layer is a black matrix (BM) whose predetermined thickness ranges from 0.01 μm to 1 μm (inclusive of 0.01 μm and 1 μm).

4. The light sensing apparatus according to claim 3, wherein the first filter layer has at least one opening having a predetermined opening area allowing the filtering device to output the other part of the ambient light to the light sensing device, and the first filter layer predetermined opening area ranges from 10% to 90% (inclusive of 10% and 90%) of the light sensing device area.

5. The light sensing apparatus according to claim 2, wherein the first filter layer is a polarizer.

6. The light sensing apparatus according to claim 2, wherein the filtering device further comprises:
a second filter layer formed between the light sensing device and the first filter layer, wherein the second filter layer has at least one color filter film formed between the first filter layer and the light sensing device, and the thickness of the color filter film ranges from 0.3 μm to 3 μm (inclusive of 0.3 μm and 3 μm).

7. The light sensing apparatus according to claim 6, wherein the color filter film has at least one opening having a predetermined opening area, the predetermined opening area is 10% to 100% (inclusive of 10% and 100%) of the light sensing device area, and the predetermined opening area allows the filtering device to output the other part of the ambient light to the light sensing device.

8. The light sensing apparatus according to claim 1, wherein the light sensing device is one of a light sensing transistor and a light sensing diode.

9. A display device, comprising:
a display panel, comprising:
a display region;
a peripheral region, comprising:
a light sensing apparatus, comprising:
a filtering device having a filter layer, wherein the filtering device is disposed in the peripheral region for filtering off a part of the ambient light and outputting the other part of the ambient light; and
a light sensing device for outputting a sensing signal according to the other part of the ambient light;
a backlight source;
a backlight control circuit, comprising:
an amplification unit for outputting an analog signal according to the sensing signal and a reference signal;
an analog/digital converter for converting the analog signal into a digital signal; and
a micro-processor for performing operation to the digital signal and outputting a backlight control signal; and
a backlight driving circuit for outputting a backlight driving signal to the backlight source according to the backlight control signal so that the brightness of backlight source is adjusted according to the ambient light.

10. The display device according to claim 9, wherein the filter layer has a predetermined thickness allowing the filtering device to output the other part of the ambient light to the light sensing device.

11. The display device according to claim 10, wherein the filter layer is a black matrix (BM) whose predetermined thickness ranges from 0.01 μm to 1 μm (inclusive of 0.01 μm and 1 μm).

12. The display device according to claim 11, wherein the filter layer has at least one opening having a predetermined opening area, the BM predetermined opening area is 10% to 90% (inclusive of 10% and 90%) of the light sensing device area, and the predetermined opening area allows the filtering device to output the other part of the ambient light to the light sensing device.

13. The display device according to claim 9, wherein the filter layer is a polarizer.

14. The display device according to claim 9, wherein the filter layer comprises at least one color filter film whose thickness ranges from 0.3 μm to 3 μm (inclusive of 0.3 μm and 3 μm).

15. The display device according to claim 14, wherein the color filter film has at least one opening having a predetermined opening area ranging from 10% to 100% (inclusive of 10% and 100%) of the light sensing device area and allowing the filtering device to output the other part of the ambient light to the light sensing device.

16. The display device according to claim 9, wherein the filter layer covers the light sensing device.

17. The display device according to claim 9, wherein the light sensing device is a thin film transistor (TFT) of the display panel.

18. A light sensing apparatus disposed on a non-display region of a flat display device, wherein the light sensing apparatus comprises:
a filter layer for filtering off a part of the ambient light and outputting the other part of the ambient light; and
a light sensing device disposed under the filter layer for outputting a sensing signal according to the other part of the ambient light.

19. The light sensing apparatus according to claim 18, wherein the filter layer is a black matrix (BM) whose predetermined thickness ranges from 0.01 μm to 1 μm (inclusive of 0.01 μm and 1 μm).

20. The light sensing apparatus according to claim 19, wherein the filter layer has at least one opening having a predetermined opening area allowing the filtering device to output the other part of the ambient light to the light sensing device, and the predetermined opening area ranges from 10% to 90% (inclusive of 10% and 90%) of the light sensing device area.

21. The light sensing apparatus according to claim 18, wherein the filter layer comprises a first color color filter film whose thickness ranges from 0.3 μm to 3 μm (inclusive of 0.3 μm and 3 μm).

22. The light sensing apparatus according to claim 21, wherein the filter layer comprises a second color color filter film stacked with the first color color filter film, and the thickness of the second color color filter film ranges from 0.3 μm to 3 μm (inclusive of 0.3 μm and 3 μm).

23. The light sensing apparatus according to claim 22, wherein the filter layer comprises a third color color filter film stacked with the second color color filter film, and the thickness of the third color color filter film ranges from 0.3 μm to 3 μm (inclusive of 0.3 μm and 3 μm).

24. The light sensing apparatus according to claim 18, wherein the filter layer covers the light sensing device.

25. The light sensing apparatus according to claim 24, wherein the light sensing device is a thin film transistor (TFT) of the display panel, and the TFT is one among single-crystal silicon TFT, amorphous silicon TFT, micro-crystal TFT and poly-crystal silicon TFT.
